(19) United States
(12) Patent Application Publication
(10) Pub. No.: US 2009/0194872 A1
(43) Pub. Date: Aug. 6, 2009

(54) DEPOPULATING INTEGRATED CIRCUIT PACKAGE BALL LOCATIONS TO ENABLE IMPROVED EDGE CLEARANCE IN SHIPPING TRAY

(75) Inventors: Ken Jian Ming Wang, Irvine, CA (US); Edward Law, Ladera Ranch, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 12/023,176

(22) Filed: Jan. 31, 2008

(51) Int. Cl. H01L 23/488; B65D 85/00; H05K 13/04

(52) U.S. Cl. 257/738; 206/706; 29/729; 257/E23.023

(57) ABSTRACT

Methods, systems, and apparatuses for integrated circuit packages, transport containers, and for transporting integrated circuit packages are provided. A transport container for an integrated circuit package includes a body and a plurality of mounting features. The body has a surface that includes a package receiving region. The plurality of mounting features is positioned in the package receiving region. A first mounting feature is positioned on a first inner surface of the package receiving region and a second mounting feature is positioned on a second inner surface of the package receiving region. The package receiving region is configured to receive an integrated circuit package such that the received package is supported by the plurality of mounting features. The first and second mounting features coincide with respective spaces in first and second edges of an array of solder balls on a surface of the package.

### BACKGROUND OF THE INVENTION

1. Field of the Invention

The present invention relates to integrated circuit packaging technology, and more particularly, to storage and shipping containers and processes for integrated circuit packages.

2. Background Art

Integrated circuit (IC) chips or dies from semiconductor wafers are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

Millions of BGA packages are manufactured each year for implementation in electronic devices. After a BGA package is assembled, the package may be placed in a shipping tray for transport. For example, the package may be shipped to an entity that integrates the package into an electronic device (e.g., a computer, cell phone, or music player). A BGA package typically must be formed in a manner that accommodates the shipping tray in which the package will be shipped. For example, in some cases, the size of the BGA package must be increased in some manner to enable the package to be shipped in a shipping tray. For instance, the package substrate may be enlarged to provide a perimeter region on the bottom surface of the substrate that is free of solder balls. When the package is placed in a recessed area of the shipping tray, the shipping tray contacts/supports the package in the perimeter region to avoid contact with the solder balls. However, such enlarging of the package to accommodate shipping is undesirable, because many BGA packages are incorporated in small profile electronic devices, such as cell phones and music players, where space is very limited.

What are needed are improved techniques for shipping integrated circuit packages that do not necessitate an enlargement in package size.

### BRIEF SUMMARY OF THE INVENTION

Methods, systems, and apparatuses are provided for integrated circuit packages, transfer containers, and transfer processes for integrated circuit packages. An integrated circuit package, such as a ball grid array (BGA) package, is formed having an array of conductive elements (e.g., solder balls, pins, etc.) on a surface. The array is depopulated, such that spaces are present where conductive elements were not formed or were removed. The integrated circuit package can be inserted into a transport container that includes mounting features for supporting the package at the positions of the spaces.

In a first example aspect, a transport container for an integrated circuit package includes a body and a plurality of mounting features. The body has a surface that includes a package receiving region. The plurality of mounting features is positioned in the package receiving region. A first mounting feature of the plurality of mounting features is positioned on a first inner surface of the package receiving region and a second mounting feature of the plurality of mounting features is positioned on a second inner surface of the package receiving region. The package receiving region is configured to receive an integrated circuit package such that the received package is supported by the plurality of mounting features. The first mounting feature coincides with a first space in a first edge of an array of solder balls on a surface of the package and the second mounting feature coincides with a second space in a second edge of the array of solder balls.

In a further aspect, an integrated circuit package includes a substrate having a surface that has a plurality of conductive pads arranged in an array of rows and columns. At least two edges of the array are not fully populated with pads. A first space in a first edge of the array and a second space in a second edge of the array are configured to respectively coincide with a first mounting feature and a second mounting feature of a transport container in which the integrated circuit package is inserted. Solder balls or other conductive elements may be coupled to the conductive pads.

In a still further aspect, an integrated circuit package may be transported. The integrated circuit package is inserted into a package receiving region in a surface of a body such that a first space in a first edge of an array of solder balls on a surface of the package and a second space in a second edge of the array are respectively in contact with a first mounting feature and a second mounting feature in the package receiving region. The package is supported in the package receiving region on the first mounting feature and the second mounting feature. The body may be transported to transport the package.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a cross-sectional side view of an example BGA package.

FIG. 2 shows a bottom view of the BGA package of FIG. 1.

FIG. 3 shows a perspective view of a transfer container that may be used to transfer the BGA package of FIG. 1.

FIG. 4 shows a top plan view of the transfer container of FIG. 3.

FIGS. 5 and 6 show perspective and side views of the BGA package of FIGS. 1 and 2 inserted in a transfer container.

FIGS. 7 and 8 show perspective and plan views of a transfer container that may be used to transfer the package of FIG. 1, according to an example embodiment of the present invention.

FIGS. 9 and 10 show bottom surfaces of example BGA packages, according to embodiments of the present invention.

FIG. 11 shows a flowchart providing a process for transporting an integrated circuit (IC) package, according to embodiments of the present invention.

FIG. 12 shows a side cross-sectional view of the package of FIG. 9 inserted into a package receiving region of a transport container, according to an example embodiment of the present invention.

FIG. 13 shows a bottom view of the package of FIG. 10 inserted into a package receiving region of a transport container, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Integrated Circuit Packages and Shipping Trays

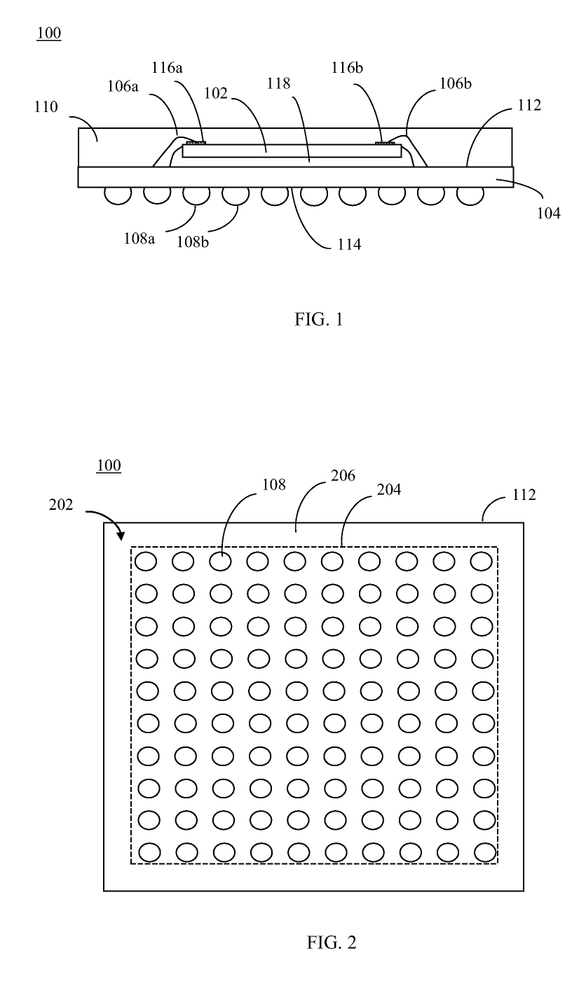

Embodiments of the present invention are applicable to a variety of types of integrated circuit packages, including ball grid array (BGA) packages. FIG. 1 shows a cross-sectional view of an example BGA package 100. BGA package 100 may be a plastic BGA (PBGA) package, a flex BGA package, a ceramic BGA package, a fine pitch BGA (FPBGA or FBGA) package, or other type of BGA package. BGA package 100 includes an integrated circuit die/chip 102, a substrate 104, bond wires (also known as “wire bonds”) 106, a plurality of solder balls 108, and an encapsulating material 110. Substrate 104 has a first (e.g., top) surface 112 that is opposed to a second (e.g., bottom) surface 114 of substrate 104. As shown in FIG. 1, die 102 is mounted to first surface 112 of substrate 104. Die 102 may be mounted to substrate 104 using an adhesive material 118.

As shown in FIG. 1, a plurality of bond wires 106 are coupled between terminals 116 of die 102 and electrically conductive features, such as traces, bond fingers, etc. (not shown in FIG. 1), at first surface 112 of substrate 104. For example, a first bond wire 106a is connected between a terminal 116a and first surface 112 of substrate 104, and a second bond wire 106b is connected between a terminal 116b and first surface 112 of substrate 104. Any number of bond wires 106 may be present, depending on a number of signals (at terminals 116) of die 102 to be coupled to conductive features of first surface 112 of substrate 104. Bond wires 106 may be wires formed of any suitable electrically conductive material, including a metal such as gold, silver, copper, aluminum, other metal, or combination of metals/alloy. Bond wires 106 may be attached according to wire bonding techniques and mechanisms well known to persons skilled in the relevant art(s).

As further shown in FIG. 1, encapsulating material 110 covers die 102 and bond wires 106 on first surface 112 of substrate 104. Encapsulating material 110 protects die 102 and bond wires 106 from environmental hazards. Encapsulating material 110 may be any suitable type of encapsulating material, including an epoxy, a mold compound, etc. Encapsulating material 110 may be applied in a variety of ways, including by a saw singulation technique, injection into a mold, etc.

A plurality of solder balls 108 (including solder balls 108a and 108b indicated in FIG. 1) is attached to second surface 114 of substrate 104. FIG. 2 shows a plan (bottom) view of second surface 114 of substrate 104. Solder balls 108 are not shown in FIG. 2. Instead, in FIG. 2, second surface 114 of substrate 104 includes an array 202 of solder balls pads 204. In the example of FIG. 2, array 202 includes one hundred solder ball pads 204 arranged in a 10 by 10 array. In other implementations, array 202 may include fewer or greater numbers of solder ball pads 204 arranged in any number of rows and columns. Solder ball pads 204 are attachment locations for solder balls 108 (shown in FIG. 1) on package 100. Solder ball pads 204 are electrically coupled through substrate 104 (e.g., by electrically conductive vias and/or routing) to the electrically conductive features (e.g., traces, bond fingers, contact regions, etc.) of first surface 112 of substrate 104 to enable signals of die 102 to be electrically connected to solder balls 108. Note that FIG. 2 shows a full array of solder ball pads 204. In some embodiments, array 202 of solder ball pads 204 may be missing some pads 204, so that array 202 is not necessarily a full array of solder balls 108 on second surface 114.

Substrate 104 may include one or more electrically conductive layers (such as at first surface 112) that are separated by one or more electrically insulating layers. An electrically conductive layers may include traces/routing, bond fingers, contact pads, and/or other electrically conductive features. For example, BGA substrates having one electrically conductive layer, two electrically conductive layers, or four electrically conductive layers are common. The electrically conductive layers may be made from an electrically conductive material, such as a metal or combination of metals/alloy, including copper, aluminum, tin, nickel, gold, silver, etc. In embodiments, substrate 104 may be rigid or may be flexible (e.g., a “flex” substrate). The electrically insulating layer(s) may be made from ceramic, plastic, tape, and/or other suitable materials. For example, the electrically insulating layer(s) of substrate 104 may be made from an organic material such as BT (bismaleimide triazine) laminate/resin, a flexible tape material such as polyimide, a flame retardant fiberglass composite substrate board material (e.g., FR-4), etc.

Other configurations for BGA package 100 are within the scope of embodiments of the present invention. For example, package 100 in FIG. 1 is a die-up type BGA package. Alternatively, package 100 may be configured as a die-down BGA package, where die 102 is mounted to a bottom surface of package 100. Furthermore, package 100 may include heat spreaders and/or heat sinks configured to spread heat within and/or outside package 100.

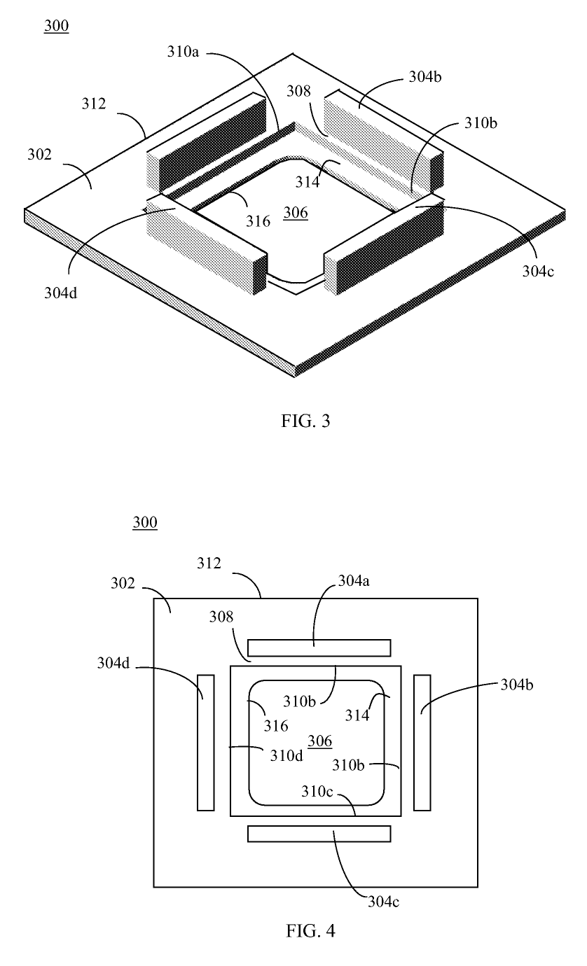

After a BGA package is assembled, the package may be placed in a shipping tray for transport. For example, the package may be shipped to an entity that integrates the package into an electronic device (e.g., a computer, cell phone, or music player). FIG. 3 shows a perspective view of a transfer container 300 that may be used to transfer package 100 of FIG. 1. FIG. 4 shows a top plan view of transfer container 300. As shown in FIGS. 3 and 4, transfer container 300 includes a planar body 312 having a surface 302 with a rectangular recessed area 306 formed therein. Recessed area 306 is surrounded on four sides respectively by first-fourth retaining walls 304a-304d, and is separated from retaining walls 304a-304d by a rectangular perimeter ledge region 308 surrounding recessed area 306. Recessed area 306 has a rectangular bottom surface 314. Four inner side surfaces 310a-310d of recessed area 306 extend upward perpendicularly from the outer edges of bottom surface 314. Bottom surface 314 of recessed area 306 has a central opening 316 that is rectangular with rounded corners.

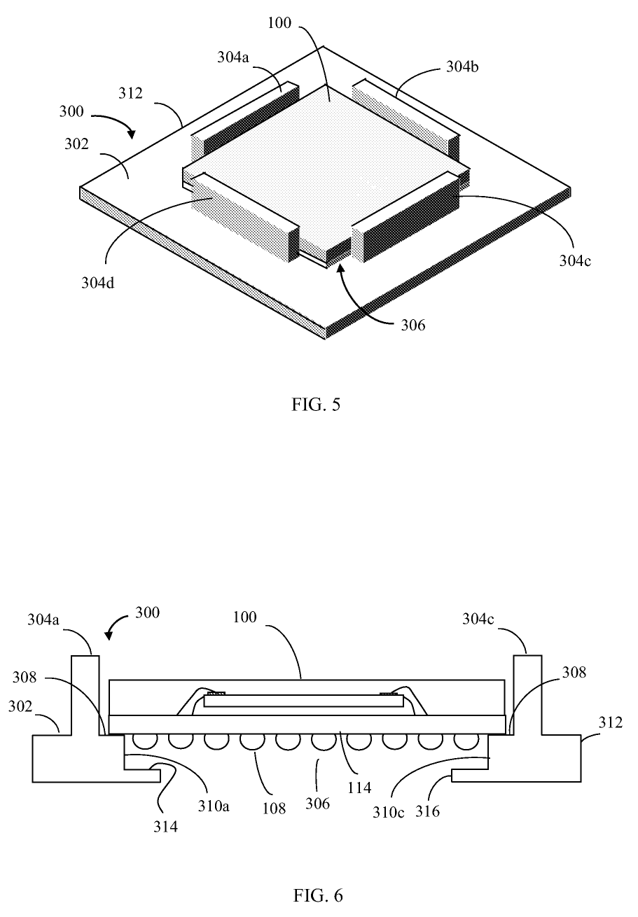

FIG. 5 shows a perspective view of BGA package 100 inserted in transfer container 300. FIG. 6 shows a side cross-sectional view of BGA package 100 inserted in transfer container 300. Package 100 may be inserted into transfer container 300 to be placed in storage, for transport from one location to another location, to enable handling of package 100 by a pick-and-place apparatus, and/or for other purpose. As shown in FIGS. 5 and 6, package 100 is inserted into recessed area 306 of transfer container 300 such that second (e.g., bottom) surface 114 of substrate 104 attaching solder balls 108 is inside recessed area 306, while a top surface of package 100 (covered by encapsulating material 110) faces away from transfer container 300. Retaining walls 304a-304d surround the four sides of package 100 to retain package 100 in recessed area 306 (e.g., to prevent package 100 from sliding laterally from recessed area 306).

BGA packages are typically configured to accommodate the shipping tray in which the package will be shipped. For example, referring to FIG. 2, a perimeter region 206 of bottom surface 114 of package 100 (outside of a central region 204 of surface 114) is free of solder balls 108. As shown in FIG. 6, when package 100 is held by transfer container 300, perimeter region 206 of package 100 contacts perimeter ledge region 308 of transfer container 300, so that package 100 rests on perimeter ledge region 308. Perimeter region 206 of surface 114 is free of solder balls 108 so that solder balls 108 do not contact perimeter ledge region 308 when package 100 is held in transfer container 300, avoiding contact with and/or damage to solder balls 108.

In the present example, the size of BGA package 100 must be increased to enable region 206 to be present and free of solder balls 108. The width of region 206 may be relatively large, such as in the range of 0.35-0.5 mm, causing package 100 to be increased in size by as much as 1 mm in width and in length. Thus, due to the requirements of transfer container 300, package 100 must be formed larger than is needed for package 100 to perform its electrical functions. This is undesirable, because many BGA packages, such as package 100, may be incorporated in small profile electronic devices, such as cell phones and music players, where space is very limited.

Embodiments of the present invention overcome the necessity for enlarging package size to meet transport container requirements. Example embodiments are further described in the following section.

### EXAMPLE EMBODIMENTS

The example embodiments described herein are provided for illustrative purposes, and are not limiting. Although described with reference to BGA packages, the examples described herein may be adapted to various types of integrated circuit packages, including pin grid array (PGA) and further types of integrated circuit packages having conductive elements such as pads/balls/pins in an array on a surface. Furthermore, additional structural and operational embodiments, including modifications/alterations, will become apparent to persons skilled in the relevant art(s) from the teachings herein.

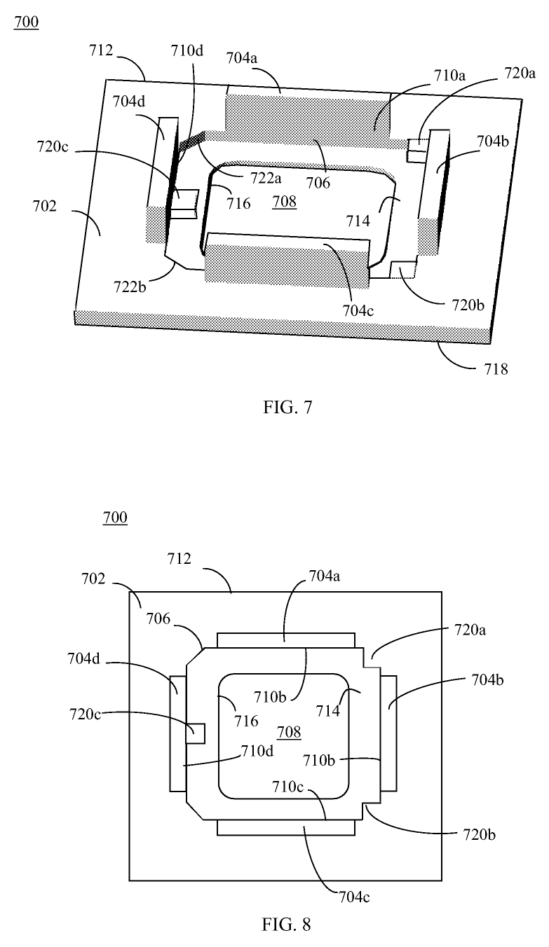

FIG. 7 shows a perspective view of a transfer container 700 that may be used to hold package 100 of FIG. 1, according to an example embodiment of the present invention. FIG. 8 shows a top plan view of transfer container 700. As shown in FIGS. 7 and 8, transfer container 700 includes a planar body 712 having opposing first and second surfaces 702 and 718. As shown in FIGS. 7 and 8, body 712 may be rectangular in shape. Alternatively, body 712 may have a different shape, including being round or having other shape. A package receiving region 708 is present at first surface 702 of body 712. In the example of FIGS. 7 and 8, package receiving region 708 includes a recessed area 706 formed in first surface 702, and includes a space above recessed area 706 between first-fourth retaining walls 704a-70b extending from first surface 702. Recessed area 706 is surrounded on four sides respectively by retaining walls 704a-704d. In an alternative embodiment, first-fourth retaining walls 704a-704d may be a single wall that forms a continuous border around recessed area 706. In still another embodiment, first surface 702 of body 712 may be co-planar with a top surface of each of first-fourth retaining walls 704a-704d, and thus first-fourth retaining walls 704a-704d may be merged with body 712.

In the example of FIGS. 7 and 8, the inner surfaces of retaining walls 704a-704d are each flush with a respective inner surface of recessed area 706, forming four inner surfaces 710a-710d of package receiving region 708. Recessed area 706 has a bottom surface 714. Inner surfaces 710a-710d extend perpendicularly from the outer edges of bottom surface 714. Bottom surface 714 of recessed area 706 has a central opening 716 that is rectangular with rounded corners. Central opening 716 is optional, and may not be present in some embodiments.

Although transfer container 300 shown in FIGS. 3 and 4 has a rectangular shaped recessed area 306, recessed area 706 of transfer container 700 does not need to be rectangular. Recessed area 706 may have any shape, such as being substantially rectangular, including being rectangular with one or more truncated corners (as shown in FIGS. 7 and 8, having truncated corners 722a and 722b) and/or rectangular with rounded corners, or may have other shape.

As shown in FIGS. 7 and 8, transfer container 700 does not include perimeter ledge region 308, which is shown in FIGS. 3 and 4 for transfer container 300. Instead, transfer container 700 includes a plurality of mounting features 720 in package receiving region 708. Mounting features 720 enable an integrated circuit package to be inserted into package receiving region 708 of transfer container 700 without requiring the package to have a perimeter edge region (e.g., perimeter region 206 shown in FIG. 2) that is free of solder balls.

In embodiments, any number of two or more mounting features 720 may be present. For example, as shown in FIGS. 7 and 8, three mounting features 720a-720c are present. First mounting feature 720a is rectangular (e.g., square) shaped, and is positioned in a first corner of recessed area 706 (and thus resides in two edges). Second mounting feature 720b is rectangular shaped, and is positioned in a second corner of recessed area 706. Third mounting feature 720c is rectangular shaped, and is positioned in a centrally along an edge of recessed area 706. First and second mounting features 720a and 720 are positioned in corners of an edge of recessed area 706 that is opposite of the edge along which third mounting feature 720c is positioned. Alternatively, first and second mounting features 720 may be positioned along respective edges of recessed area 706, while third mounting feature 720 is positioned in a corner of recessed area 706.

Mounting features 720 may be positioned at the corners/edges of recessed area 706 in any configuration, as desired for a particular application. For example, in an embodiment, four mounting features 720 may be present, with each mounting feature 720 positioned in a respective corner of recessed area 706 (similarly to first and second mounting features 720a and 720b). Alternatively, four mounting features 720 may be present, with each mounting feature 720 positioned along a respective edge of recessed area 706 (e.g., similarly to third mounting feature 720c). In embodiments, two, three, or even more mounting features 720 may be present on a single edge of recessed area 706, if desired.

Mounting features 720 may have any shape. For example, mounting features 720 may be rectangular as shown in FIGS. 7 and 8, or may have other shape, such as round, elliptical, triangular, other polygon, or irregular shape. Furthermore, mounting features 720 may have any size, as further described below. As shown in FIG. 7, the surface of mounting features 720 may be coplanar with first surface 702 of body 712. Alternatively, the surface of mounting features 720 may be recessed with respect to first surface 702, or may be protruding with respect to first surface 702. Mounting features 720 may be formed as a portion of body 712 as shown in FIGS. 7 and 8, or may be separately formed and attached to body 712 by an adhesive material and/or attachment process, as described elsewhere herein or otherwise known.

Transfer container 700 can be formed in any manner. For instance, body 712 and retaining walls 704a-704d may be formed as a single piece. For example, body 712, retaining walls 704a-704d, recessed region 706, mounting features 720, and opening 716 (when present) may be formed by inserting a material into a mold (e.g., an epoxy, a polymer, a metal, etc.), by machining a base material (e.g., a metal, a polymer, glass, etc.), or by other formation technique. Alternatively, body 712 and retaining walls 704a-704d may be formed separately, and retaining walls 704a-704d may subsequently be attached to body 712 by an adhesive material such as an epoxy, a glue, solder, or other adhesive material, and/or by a process such as welding, soldering, etc. Recessed region 706 and opening 716 (when present) may optionally be formed by a machining or other technique subsequent to attaching retaining walls 704a-704d with body 712. Any other technique or combination of techniques may be used to form transfer container 700. Furthermore, transfer container 700 may formed in a sheet/array of transfer containers 700.

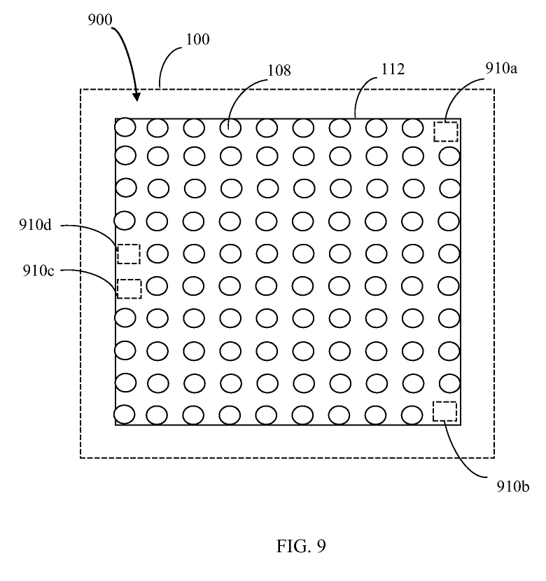

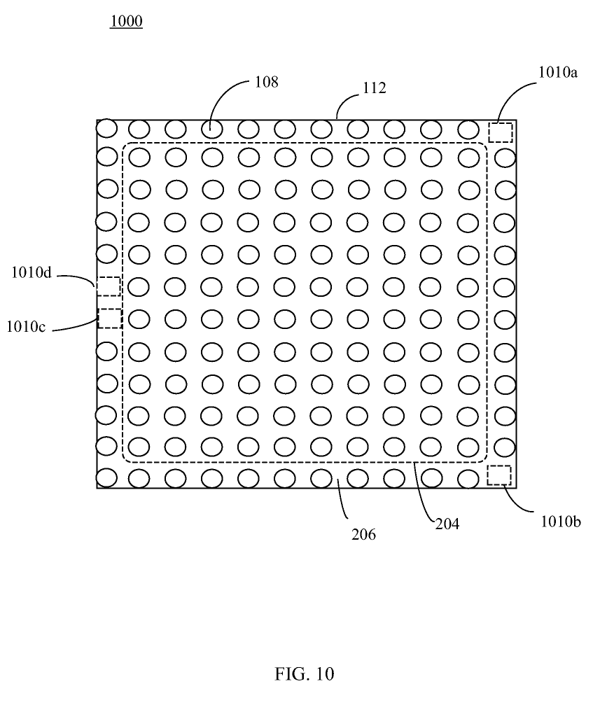

BGA packages, such as package 100 shown in FIGS. 1 and 2, may be modified to conform to transfer container 700, providing advantages. For example, FIGS. 9 and 10 show bottom surfaces of example BGA packages 900 and 1000, respectively, according to embodiments of the present invention. As shown in FIG. 9, package 900 is smaller in size than package 100 (an outline of package 100 is indicated by a dotted line in FIG. 9), being reduced in size with respect to package 100 by the area of perimeter region 206 shown in FIG. 2. Furthermore, package 900 has an array of solder balls 108 of the same dimensions (10 by 10) as array 202 of package 100 shown in FIG. 2, with four solder balls depopulated, as indicated by spaces 910a-910d. Spaces 910 where solder balls are not present are positioned to coincide with mounting features 720 of transport container 700. For instance, in FIG. 9, space 910a is positioned to coincide with second mounting feature 720b, space 910b is positioned to coincide with first mounting feature 720a, and spaces 910c and 910d are positioned to coincide with third mounting feature 720c.

In embodiments, a mounting feature 720 may have a size corresponding to any number of spaces 910. For example, mounting features 720a and 720 each correspond to a single space (spaces 910b and 910a, respectively), and mounting feature 720c corresponds to two spaces 910a and 910b. A mounting feature 720 may have a size corresponding to three or more spaces, if desired. Furthermore, in an embodiment, mounting feature 720 may correspond to spaces 910 in an outermost row of the solder ball array of package 900 and/or to spaces 910 located in interior rows of the solder ball array.

Package 900 may be inserted in a transport container configured similarly to transport container 700 for transport. Furthermore, package 900 is reduced in size relative to package 100 shown in FIGS. 1 and 2, because package 900 may be supported in transport container 700 by mounting features 720 and thus perimeter region 206 is not present. As a result, in the embodiment of FIG. 9, transport container 700 enables a smaller package size.

Package 1000 shown in FIG. 10 has a same size as package 100 shown in FIGS. 1 and 2. However, package 900 has an array of solder balls 108 (12 by 12) that is larger than array 202 (10 by 10) of package 100 shown in FIG. 2. Similarly to the embodiment of FIG. 9, the array of package 900 has four solder balls removed, as indicated by spaces 1010a-1010d. Spaces 1010 where solder balls are not present are positioned to coincide with mounting features 720 of transport container 700. For instance, in FIG. 10, space 1010a is positioned to coincide with second mounting feature 720b, space 1010b is positioned to coincide with first mounting feature 720a, and spaces 1010c and 1010d are positioned to coincide with third mounting feature 720c.

Package 1000 may be inserted in a transport container configured similarly to transport container 700 for transport. Furthermore, package 1000 has the same size as package 100 shown in FIGS. 1 and 2, but has a larger pinout because solder balls 108 are present in perimeter region 206 for package 1000. Thus, in the example of FIG. 10, transport container 700 enables a same sized package to have a larger pinout, enabling a package having a larger amount of I/O, power, ground, and/or test signals. Thus, as illustrated in FIGS. 9 and 10, embodiments of the present invention can provide package size advantages, enabling smaller package sizes and packages with higher pinout at a same size.

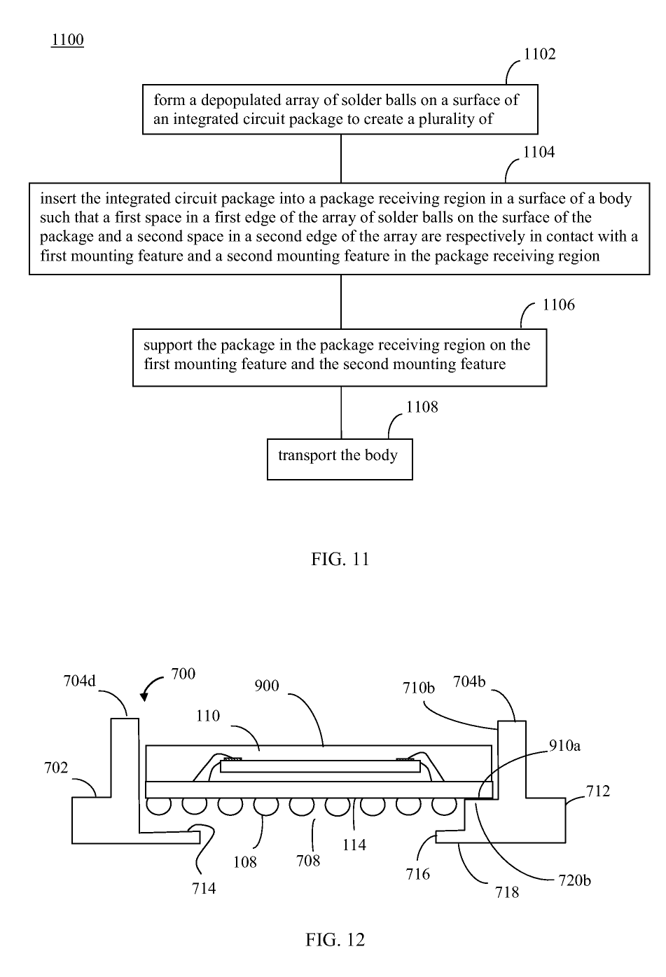

FIG. 11 shows a flowchart 1100 providing a process for transporting an integrated circuit (IC) package, according to embodiments of the present invention. Not all steps of flowchart 1100 must be performed in all embodiments. Other structural and operational embodiments will be apparent to persons skilled in the relevant art(s) based on the discussion regarding flowchart 1100. Flowchart 1100 is described as follows.

Flowchart 1100 begins with step 1102. In step 1102, a depopulated array of solder balls on a surface of an integrated circuit package is formed to create a plurality of spaces. For example, as shown in FIGS. 9 and 10, spaces 910/1010 may be formed in an array of solder balls on a surface of a BGA package to form a depopulated array. The array may be depopulated by forming the solder ball array in a depopulated manner, or by removing solder balls that have been attached in the array.

In step 1104, the integrated circuit package is inserted into a package receiving region in a surface of a body such that a first space in a first edge of the array of solder balls on the surface of the package and a second space in a second edge of the array are respectively in contact with a first mounting feature and a second mounting feature in the package receiving region. For example, FIG. 12 shows a side cross-sectional view of package 900 inserted into package receiving region 708 of transport container 700, according to an example embodiment of the present invention. As shown in FIG. 12, package 900 is inserted into recessed area 706 of transfer container 700 such that surface 114 attaching solder balls 108 is inside recessed area 706, while a top surface of package 900 (covered by encapsulating material 110 in the current example) faces away from transfer container 700. Retaining walls 704a-704d surround the four sides of package 900 to retain package 900 in recessed area 706 (e.g., to prevent package 900 from sliding laterally from recessed area 706). The bottom surface 114 of package 900 at spaces 910 contacts mounting features 720 (space 910a is shown contacting mounting feature 720b in FIG. 12), so that package 900 is supported on mounting features 720 at spaces 910.

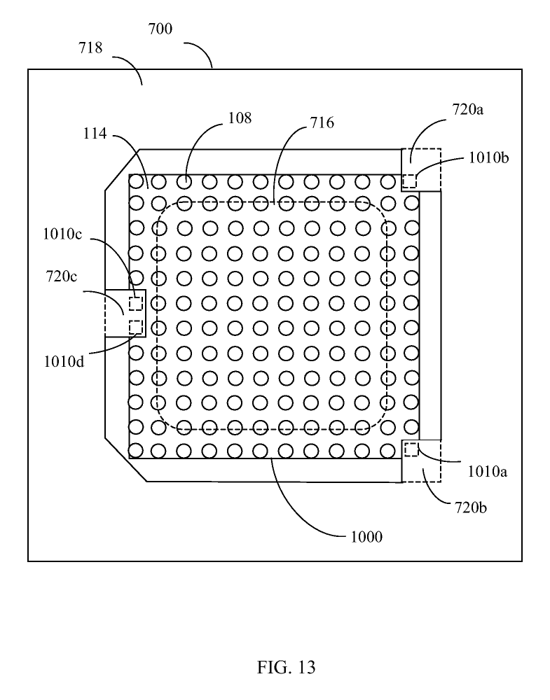

In step 1106, the package is supported in the package receiving region on the first mounting feature and the second mounting feature. For example, as shown in FIG. 9, package 900 is supported in package receiving area 708 by mounting features 720 (e.g., mounting feature 720b shown in FIG. 12). In another example, FIG. 13 shows a bottom view of package 1000 of FIG. 10 inserted into package receiving region 708 of transport container 700. In FIG. 13, surface 718 of transport container 700 is transparent for illustrative purposes. As shown in FIG. 13, bottom surface 114 of package 1000 at spaces 1010a, 1101b, 1010c, and 1010d contacts mounting features 720b, 720a, and 720c (mounting feature 720c contacts package 1000 at spaces 1010c and 1010d), respectively, so that package 1000 is supported on mounting features 720 at spaces 1010.

In step 1108, the body is transported. As described above, a package inserted in transport container 700, such as packages 900 and 1000, may be transported in any manner and for any purpose, including to be placed in storage, for transport from one location to another location, to enable handling of the package by a pick-and-place apparatus, and/or for other purpose.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A transport container for an integrated circuit package, comprising:
a body having a surface that includes a package receiving region; and
a plurality of mounting features in the package receiving region;
wherein a first mounting feature of the plurality of mounting features is positioned on a first inner surface of the package receiving region and a second mounting feature of the plurality of mounting features is positioned on a second inner surface of the package receiving region; and
wherein the package receiving region is configured to receive an integrated circuit package such that the received package is supported by the plurality of mounting features, wherein the first mounting feature coincides with a first space in a first edge of an array of solder balls on a surface of the package and the second mounting feature coincides with a second space in a second edge of the array of solder balls.

2. The transport container of claim 1, wherein the package receiving region includes a substantially rectangular opening in the surface of the body.

3. The transport container of claim 2, wherein the package receiving region further includes a retaining structure on the surface of the body that at least partially surrounds the opening in the surface of the body.

4. The transport container of claim 3, wherein an inner surface of the retaining structure is flush with an inner surface of the substantially rectangular opening.

5. The transport container of claim 2, wherein the first mounting feature is located at a corner of the substantially rectangular opening.

6. The transport container of claim 1, wherein the first mounting feature is located at a central location on the inner surface of the substantially rectangular opening, wherein the first space is located between first and second solder balls in the first edge of the array.

7. The transport container of claim 1, wherein a third mounting feature is positioned on a third inner surface of the package receiving region, wherein the third mounting feature coincides with a third space in a third edge of the array of solder balls.

8. The transport container of claim 1, wherein the first mounting feature coincides with the first space and a third space in the first edge of the array that is adjacent to the first space.

9. An integrated circuit package, comprising:
a substrate having a surface that has a plurality of conductive pads arranged in an array of rows and columns, wherein at least two edges of the array are not fully populated with pads, wherein a first space in a first edge of the array and a second space in a second edge of the array are configured to respectively coincide with a first mounting feature and a second mounting feature of a tray in which the integrated circuit package is inserted.

10. The package of claim 9, further comprising:
a plurality of solder balls coupled to the conductive pads.

11. The package of claim 9, wherein the first space is located in a corner of the array.

12. The package of claim 9, wherein the first space is located between first and second solder balls coupled to conductive pads in the first edge of the array.

13. The package of claim 9, wherein a third space is located in the first edge adjacent to the first space, wherein the first space and third space are configured to coincide with the first mounting feature.

14. A method for transporting an integrated circuit package, comprising:
inserting the integrated circuit package into a package receiving region in a surface of a body such that a first space in a first edge of an array of solder balls on a surface of the package and a second space in a second edge of the array are respectively in contact with a first mounting feature and a second mounting feature in the package receiving region;
supporting the package in the package receiving region on the first mounting feature and the second mounting feature; and
transporting the body.

15. The method of claim 14, wherein the package receiving region includes a substantially rectangular opening in the surface of the body, wherein said inserting comprises:
inserting the package into the substantially rectangular opening.

16. The method of claim 15, wherein the package receiving region further includes a retaining structure on the surface of the body that at least partially surrounds the opening in the surface of the body, wherein said inserting further comprises:
enclosing the package on four sides by the retaining structure.

17. The method of claim 15, wherein the first mounting feature is located at a corner of the substantially rectangular opening, wherein said supporting comprises:
supporting the package in the substantially rectangular opening on the corner located first mounting feature and the second mounting feature.

18. The method of claim 14, wherein the first mounting feature is located at a central location on the inner surface of the substantially rectangular opening, wherein the first space is located between first and second solder balls coupled to solder balls in the first edge of the array, wherein said supporting comprises:
supporting the package in the substantially rectangular opening on the centrally located first mounting feature and the second mounting feature.

19. The method of claim 14, wherein a third mounting feature is positioned on a third inner surface of the package receiving region, wherein said supporting comprises:
supporting the package in the package receiving region on the first, second, and third mounting features.

20. The method of claim 14, wherein a third space is located in the first edge adjacent to the first space, wherein said inserting comprises:
inserting the integrated circuit package into the package receiving region such that the first and third space in the first edge are in contact with the first mounting feature.
